(19) United States
(12) Patent Application Publication
(10) Pub. No.: US 2015/0194753 A1
(43) Pub. Date: Jul. 9, 2015

(54) MID-PLANE BOARD-TO-BOARD CONNECTORS

(71) Applicant: Apple Inc., Cupertino, CA (US)

(72) Inventors: John Raff, Menlo Park, CA (US); Robert Scritzky, Sunnyvale, CA (US)

(73) Assignee: APPLE INC., Cupertino, CA (US)

(21) Appl. No.: 14/664,900

(22) Filed: Mar. 22, 2015

Related U.S. Application Data
(60) Provisional application No. 61/969,082, filed on Mar. 21, 2014.

(51) Int. Cl. H01R 12/71; H05K 1/18; H05K 3/36; H05K 1/14

(52) U.S. Cl. CPC H01R 12/716; H05K 1/144; H05K 1/183; H05K 3/361

(57) ABSTRACT

Board-to-board connectors that may consume a reduced amount of space in an electronic device by having a reduced height, provide a durable and reliable connection, and may be easy to manufacture. In one example, a board-to-board connector having a reduced height may reside at least partially in a recess or opening in a printed circuit board or other substrate.

### CROSS-REFERENCES TO RELATED APPLICATIONS

This application claims the benefit of U.S. provisional application No. 61/969,082, filed on Mar. 21, 2014, titled “MID-PLANE BOARD-TO-BOARD CONNECTORS,” which is incorporated by reference.

### BACKGROUND

The number of types of electronic devices that are commercially available has increased tremendously the past few years and the rate of introduction of new devices shows no signs of abating. Devices, such as tablet, laptop, netbook, desktop, and all-in-one computers, cell, smart, and media phones, storage devices, portable media players, navigation systems, monitors, and others, have become ubiquitous.

The functionality of these devices has likewise greatly increased. This in turn has led to increased complexity inside of these electronic devices. For example, several types of boards, such as flexible circuit boards, printed circuit boards, and others, are often included in a single device. These boards may be connected together using board-to-board connectors.

But these connectors may consume a relatively substantial amount of space or volume inside an electronic device. This may result in either the device having a reduced functionality, a larger size, or a combination of the two. Smaller connectors may save space, allowing more functionality in a device, they may allow a device to be smaller, or a combination of the two.

Each connector may have a footprint or length and width in an X and Y direction on a printed circuit board or other substrate, and a height in a Z direction. To the extent that a height or Z can be reduced, the volume consumed by a board-to-board connector can be reduced. Such a reduction in height or Z may also bring the two connected boards into closer proximity, thereby reducing what may otherwise be wasted space between them.

Also, these board-to-board connectors should typically be reliable, otherwise disconnections between circuits and components could occur leading to a loss of functionality or failure of the device. They should also be durable. This way, if the device is dropped or otherwise jarred, a disconnection may be avoided.

Further board-to-board connectors may also be somewhat complicated to manufacture. This may lead to increased device costs. Connectors that may be easier to manufacture may provide reduce costs.

Thus, what is needed are board-to-board connectors that may consume a reduced amount of space in an electronic device by having a reduced height, may provide a durable and reliable connection, and may be easy to manufacture.

### SUMMARY

Accordingly, embodiments of the present invention may provide board-to-board connectors that may consume a reduced amount of space in an electronic device by having a reduced height, may provide a durable and reliable connection, and may be easy to manufacture.

An illustrative embodiment of the present invention may provide board-to-board connectors that have a reduced height. In one example, a board-to-board connector having a reduced height may reside at least partially in a recess or opening in a printed circuit board or other appropriate substrate.

In an embodiment of the present invention, an opening may be formed from a top side to a bottom side of a printed circuit board or other substrate. The opening may be formed using a router or other appropriate tool or method. For example, a number of boards may be stacked and a router may be used to form an opening in each board in the stack. A board-to-board connector receptacle or insert may then be placed in the opening.

In one example, a board-to-board connector receptacle may be placed in the opening. The receptacle may include a receptacle housing that may provide support for a number of contacts. These contacts may have contacting portions arranged to be soldered to pads or contacts on a top side of the printed circuit board near the opening. The contacts may be arranged to mate with contacts on a corresponding connector insert or receptacle. The receptacle housing may include a recess around a raised central portion, the contacts having contacting portions on sides of the recess. The recess may be arranged to accept a raised portion of a connector insert, where contacts on the connector insert are located on the raised portion of the connector insert. The raised central portion of the receptacle may be arranged to fit in a recess in the raised portion of the connector insert. The receptacle housing may include one or more overlap portions to overlap the printed circuit board or other substrate in order to provide increased mechanical support.

In another embodiment of the present invention, a recess may be formed in a top surface of a printed circuit board or other substrate. The recess may be formed using a router or other appropriate method. A board-to-board connector portion may be placed in the recess. For example, a board-to-board connector insert or receptacle may be placed in the recess.

An illustrative embodiment of the present invention may provide board-to-board connectors that may provide a durable and reliable connection. This may be of particular value in mobile devices, where the need for reduced size and durability is acute. For example, it may be useful to increase the retention force in a board-to-board connector in a mobile device, since such devices may be likely to experience shocks and vibration that may otherwise disconnect a connector. For example, embodiments of the present invention are particularly well-suited to connecting flexible circuit boards to printed circuit boards. In such a situation, a cowling may be used to act as a stiffener for the flexible circuit board to improve reliability and durability of a connection between the connector insert and connector receptacle. The cowling may be attached or otherwise fixed to the flexible circuit board. For example, the cowling may be attached using an adhesive, tape, or other material. In other embodiments of the present invention, the cowling may be formed or molded on the flexible circuit board.

Another illustrative embodiment of the present invention may provide a durable connection by providing a connector receptacle having contacts arranged to provide a strong lateral force such that a durable and reliable connection to corresponding contacts in a connector receptacle is achieved.

A specific embodiment of the present invention may provide a board-to-board connector receptacle having a plurality of contacts to mate with corresponding contacts in a board-to-board connector insert. Each contact may include a first lateral surface mount contact portion, a first vertical portion extending in a downward direction, a second lateral portion attached to the first vertical portion and extending away from the first lateral surface mount contact portion, and a second vertical portion attached to the second lateral portion and extending in an upward direction. The first vertical portion may include a first contacting surface and the second vertical portion may include a second contacting surface. The first and second contacting surfaces may form electrical connections with contacts of the connector insert.

One or more contacts may further include a third vertical portion connected to the first lateral surface mount contact portion and extending in a downward direction, a third lateral portion attached to the third vertical portion and extending away from the first lateral surface mount contact portion, a fourth vertical portion attached to the third lateral portion and extending in a downward direction, and a fourth lateral portion attached between the fourth vertical portion and the first vertical portion. In other embodiments of the present invention, the first lateral surface mount portion may connect directly to, or be merged with, the first vertical portion to reduce a length of the contact.

An illustrative embodiment of the present invention may provide board-to-board connector systems that are readily manufactured. An illustrative embodiment of the present invention may provide a method of assembling a board-to-board connection system for an electronic device, the method including receiving a printed circuit board, forming a first region in a surface of the printed circuit board, receiving a housing for a board-to-board receptacle, inserting a plurality of contacts into the housing, the plurality of contacts to mate with corresponding contacts of a connector insert, inserting the housing and plurality of contacts into the first region, attaching a first lateral surface mount contact portion of each of the plurality of contacts to a corresponding pad on a surface of the printed circuit board near the first region, attaching a board-to-board insert to a flexible circuit board, and inserting the board-to-board insert into the board-to-board receptacle. The first region may be a recess in a surface of a printed circuit board, or it may be an opening in the printed circuit board.

In various embodiments of the present invention, a connector for a board-to-board connector system, for example a connector receptacle, may be located in a recess in a printed circuit board or other appropriate substrate. In this case, a bottom portion of a printed circuit board below the recess may provide mechanical support for the connector receptacle. In other embodiments of the present invention, it may be easier to form an opening through the board from a top side to a bottom side than it would be to form a recess in a top side of a printed circuit board. With such an opening, support from the printed circuit board itself may be absent or reduced. Accordingly, embodiments of the present invention may include a shell or other support mechanisms or a combination of a shell and support mechanisms. These support mechanisms may provide support for a housing of the connector receptacle, instead of or along with the overlap portions described above. This support may help keep a connector receptacle from being pushed through the opening when a connector insert is inserted into the connector receptacle. These support mechanisms may further provide support for the individual contacts of a connector receptacle.

An illustrative embodiment of the present invention may provide a connector receptacle having a shell on the bottom of the connector. This shell may be arranged such that a bottom side of the shell may be approximately aligned in the plane of a bottom of the printed circuit board into which the connector receptacle is placed. This alignment may properly align the connector receptacle in the printed circuit board when the connector receptacle and printed circuit board are placed on flat surface, such a device enclosure. In various embodiment of the present invention, this shell may be plastic or metal. When the shell is metallic, it may be attached to one or more ground contacts on the connector receptacle to provide electromagnetic shielding.

In other embodiments of the present invention, other structures may be used in place of, or in conjunction with, the shell. For example, a supporting plane may be placed between a housing of the connector receptacle and the shell. When the shell is plastic, a supporting plane formed of metal may be placed between the housing and the shell. This metal supporting plane may be connected to one or more ground contacts on the connector receptacle. Again, this may allow for electromagnetic interference shielding. Where a metallic supporting plane is used, an insulating layer may be placed between the contacts of the connector receptacle and the supporting plane to provide electrical isolation.

Embodiments of the present invention may be used to connect two or more boards together, where the two or more boards include flexible circuit boards, printed circuit boards, or other appropriate boards. For example, embodiments of the present invention may be used to connect two flexible circuit boards, two printed circuit boards, two flexible circuit boards and one printed circuit board, or other combination.

An illustrative embodiment of the present invention may provide board-to-board connectors where contacts in a receptacle form electrical connections with traces or planes in or on a first or printed circuit board. Similarly, contacts in an insert may form electrical connections with traces or planes in or on a second or flexible circuit board. Contacts in the insert may mate with contacts in the receptacle. In this way, traces and planes on a first or printed circuit board may be electrically connected to traces and planes on a second or flexible circuit board. These various connections may convey power supplies, ground, data, and other types of voltages and signals.

In various embodiments of the present invention, contacts and other conductive portions of a board-to-board connector, such as the shell or supporting plane, may be formed by stamping, metal-injection molding, machining, micro-machining, 3-D printing, or other manufacturing process. The insert and receptacle contacts and other conductive portions may be formed of stainless steel, steel, copper, copper titanium, phosphor bronze, or other material or combination of materials. They may be plated or coated with nickel, gold, or other material. The insert and receptacle housings, and other portions such as the shell or supporting plane, may be formed using injection or other molding, 3-D printing, machining, or other manufacturing process. The insert and receptacle housings and other nonconductive portions may be formed of silicon or silicone, rubber, hard rubber, plastic, nylon, liquid-crystal polymers (LCPs), or other nonconductive material or combination of materials.

Various embodiments of the present invention may incorporate one or more of these and the other features described herein. A better understanding of the nature and advantages of the present invention may be gained by reference to the following detailed description and the accompanying drawings.

### BRIEF DESCRIPTION OF THE DRAWINGS

FIG. 1 illustrates a board-to-board connector according to an embodiment of the present invention;

FIG. 2 illustrates a cutaway side view of a board-to-board connector according to an embodiment of the present invention;

FIG. 3 illustrates a board-to-board connector system where a connector insert has been inserted into a connector receptacle according to an embodiment of the present invention;

FIG. 4 illustrates a side view of a board-to-board connector system according to an embodiment of the present invention;

FIG. 5 illustrates a top view of a connector receptacle according to an embodiment of the present invention;

FIG. 6 illustrates an underside view of a connector receptacle according to an embodiment of the present invention; and

FIG. 7 illustrates a board-to-board connector system including a connector receptacle having support mechanisms according to an embodiment of the present invention.

### DESCRIPTION OF EXEMPLARY EMBODIMENTS

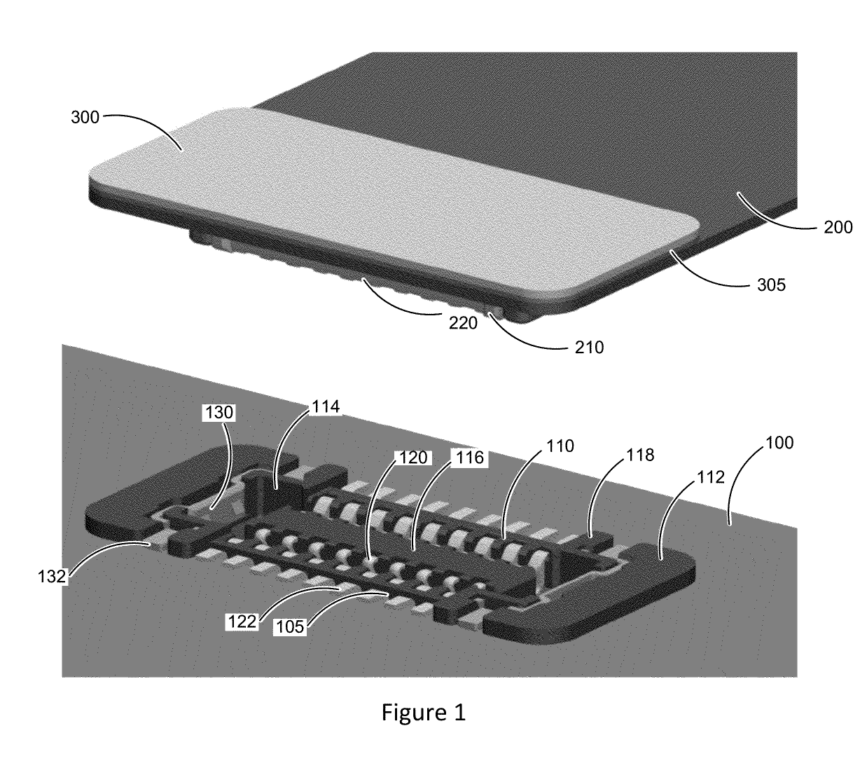

FIG. 1 illustrates a board-to-board connector according to an embodiment of the present invention. This figure, as with the other included figures, is shown for illustrative purposes and does not limit either the possible embodiments of the present invention or the claims.

Again, embodiments of the present invention may provide board-to-board connectors having a reduced height. In this embodiment of the present invention, a receptacle for a board-to-board connector may be located in recess or opening 105 in a printed circuit board or other appropriate substrate 100. This connector receptacle may include housing 110 supporting a number of contacts 120. Housing 110 may include a recess 114 around a central island or raised portion 116. Housing 110 may further include overlap portions 118 and 112 for mechanical support. Specifically, overlap portions 112 and 118 may be located along ends or sides of housing 110 and may be placed over a solid portion of printed circuit board 100, as opposed to being over opening or recess 105.

Contacts 120 may include lateral contacting portions 122, which may be a surface mount or other type of contacts. Lateral contacting portions 122 may be arranged to be soldered to pads or contacts on a surface of printed circuit board 100.

This receptacle may include ground contacts or hold downs 130 at ends of housing 110. Ground contacts or hold downs 130 may include surface mount contacting portions 132. Surface mount contacting portions 132 may be arranged to be soldered to pads or contacts on printed circuit board 100. Ground contacts or hold downs 130 may accept a corresponding portion on a connector insert to secure the connector insert when it is inserted in the connector receptacle.

A connector insert may include housing 210 supporting a plurality of contacts 220 for mating with contacts 120 of the connector receptacle. The connector insert may be attached to flexible circuit board 200. To improve reliability of a connection between the insert and receptacle, cowling or stiffener 300 may be placed over a portion of flexible circuit board 200, for example above the connector insert. Cowling 300 may be attached to flexible circuit board 200 by using tape, adhesives, or other material 305.

Recess 114 may be arranged to accept a raised portion of housing 210 of the connector insert. Raised central portion 116 may be arranged to fit in a recess of raised portion 210 of the connector insert.

In this example, a connector receptacle is shown as being at least partially located in recess or opening 105. In other embodiments of the present invention, a connector insert may be at least partially located in an opening or recess 105. Also, while recess or opening 105 is shown as being located in a top surface of printed circuit board 100, in other embodiments of the present invention, it may be located in a flexible circuit board, or other appropriate substrate. Also, while embodiments of the present invention are particularly well-suited to joining traces or circuitry on a flexible circuit board to traces and circuitry on a printed circuit board, such as flexible circuit board 200 and printed circuit board 110, in other embodiments of the present invention, traces and circuits on other types of boards, or traces and circuits on more than two boards, may be joined. Also, while in these examples flexible circuit boards are connected to printed circuit boards, in other embodiments of the present invention, two or more flexible circuit boards, or two or more printed circuit boards may be connected together. These various connections may convey power supplies, ground, data, and other types of voltages and signals.

By placing the receptacle at least partially in recess or opening 105, an overall height of the combined board-to-board connector structure may be reduced. This may reduce a volume or space inside an electronic device consumed by this connection. In other embodiments of the present invention, a connector insert may be at least partially located in a recess or opening 105 in board 100. Also, a connector insert or receptacle may be located in an opening or recess in flexible circuit board 200.

In various embodiments of the present invention, printed circuit board 100 may be a main logic board, a motherboard, or other type of printed circuit board. Printed circuit board 100 and flexible circuit board 400 may be located in various electronic devices, such as portable computing devices, tablets, desktop computers, laptops, all-in-one computers, cell phones, smart phones, media phones, storage devices, portable media players, navigation systems, monitors and other devices.

In various embodiments of the present invention, contacts 120, 220, and 130, and other conductive portions of a board-to-board connector, may be formed by stamping, metal-injection molding, machining, micro-machining, 3-D printing, or other manufacturing process. The insert and receptacle contacts 120, 220, and 130 may be formed of stainless steel, steel, copper, copper titanium, phosphor bronze, or other material or combination of materials. They may be plated or coated with nickel, gold, or other material. The insert and receptacle housings 110 and 210 may be formed using injection or other molding, 3-D printing, machining, or other manufacturing process. The insert and receptacle housings 110 and 210 may be formed of silicon or silicone, rubber, hard rubber, plastic, nylon, liquid-crystal polymers (LCPs), or other nonconductive material or combination of materials. Cowling 300 may be formed of plastic, metal, or other material. For example, it may be a grounded piece of metal to act as a shield.

Again, recess or opening 105 may be formed using a router or by other methods. In various embodiments of the present invention, openings 105 may be formed in each printed circuit board in a stack of printed circuit boards using a router. Forming openings in several boards at once may help to increase manufacturing throughput. A cutaway view of a board-to-board connector system where a connector is at least partially located in an opening is shown in the following figure.

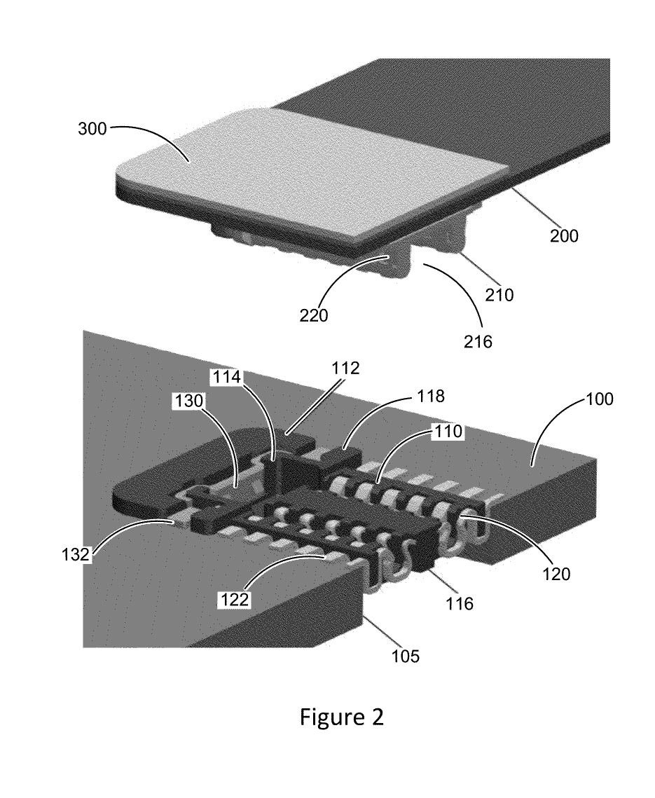

FIG. 2 illustrates a cutaway side view of a board-to-board connector according to an embodiment of the present invention. As before, a receptacle including housing 110 supporting a number of contacts 120 may be located at least partially in an opening 105 in printed circuit board 100. Again, housing 110 may include recess 114 around a central raised portion 116. Contacts 120 may include surface mount contacting portions 122. Ground contacts 130 may be located near ends of housing 110 and may include surface mount contacting portions 132. Housing 110 may further include board overlap portions 112 and 118. Board overlap portions 112 and 118 may be located over a solid portion of printed circuit board 100, as opposed to being located over opening 105. In this way, board overlap portions 112 and 118 may provide mechanical support for housing 110 and may help prevent the connector receptacle from being pushed though opening 105 when the connector insert is inserted into the connector receptacle.

The connector insert may include housing 210 supporting a number of contacts 220. Contacts 220 of the connector insert may mate with contacts 120 in the connector receptacle. Contacts 220 may form electrical connections with traces in flexible circuit board 200. As before, cowling or stiffener 300 may be used to provide mechanical support and improve a connection between the connector insert and the connector receptacle.

As before, connector insert housing 210 may be arranged to fit in recess 114 in receptacle housing 110. The connector insert housing 210 may include recess 216 arranged to accept raised central portion 116 of housing 110 of the connector receptacle. An example is shown in the following figure.

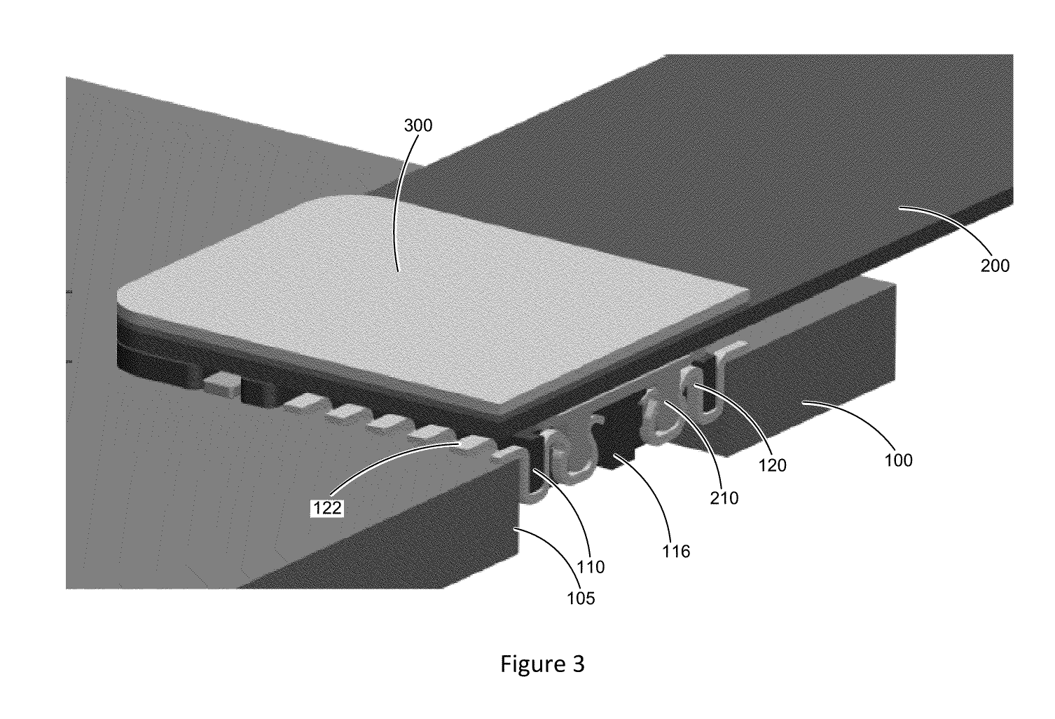

FIG. 3 illustrates a board-to-board connector system where a connector insert has been inserted into a connector receptacle according to an embodiment of the present invention. Again, a connector receptacle including housing 110 supporting a number of contacts 120 may be at least partially located in opening 105 in printed circuit board 100. A connector insert may include housing 210. Housing 210 may be inserted into a recess in the connector receptacle such that contacts (not shown) on housing 210 of the connector insert mate with contacts 120 in the connector receptacle. Contacts 120 may include lateral surface mount contacting portions 122.

Again, the connector insert may be attached to flexible circuit board 200. A cowling or stiffener 300 may be used for mechanical support and to improve the reliability of the connection between the connector insert and connector receptacle.

Embodiments of the present invention may provide contacts for a connector receptacle that provide a durable electrical connection with contacts of a connector insert. An example is shown in the following figure.

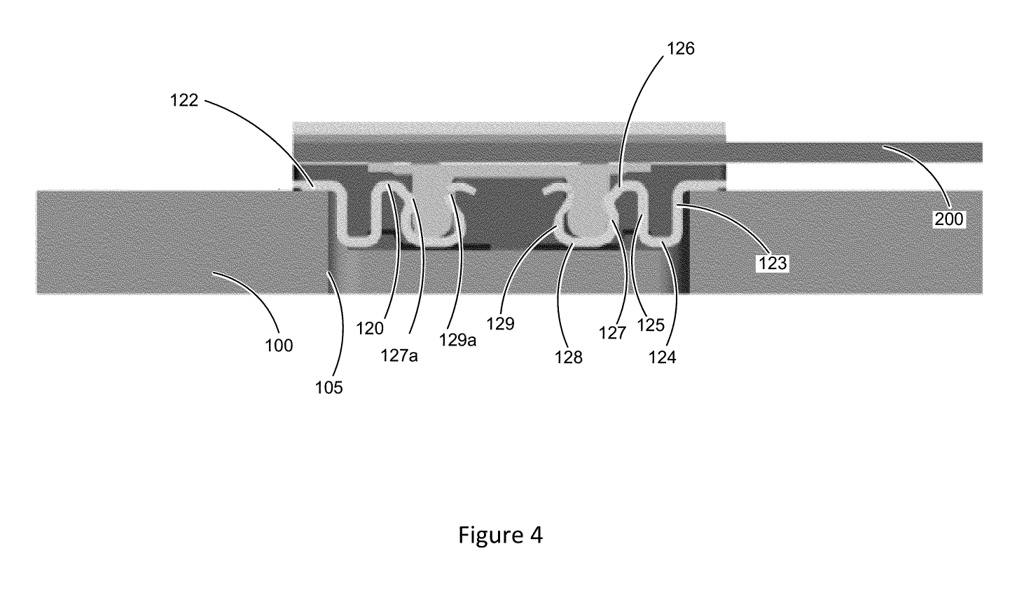

FIG. 4 illustrates a side view of a board-to-board connector system according to an embodiment of the present invention. A connector receptacle may be at least partially located in opening 105 in printed circuit board or other substrate 100. Contacts 120 may form electrical connections between traces on printed circuit board 100 and contacts (not shown) on a connector insert. The connector insert contacts may form electrical connections with traces on flexible circuit board 200.

Contacts 120 may be arranged to provide a strong inward lateral force against contacts of the connector insert. Specifically, contacts 120 may include a lateral surface mount contacting portion 122. Lateral surface mount contacting portions 122 may be arranged to be soldered to pads or contacts on a surface of printed circuit board or other appropriate substrate 100. Contacts 120 may include a first vertical portion 127 extending in a downward direction. First vertical portion 127 may include a contacting surface 127a for mating with a contact of the connector insert. Contact 120 may further include a second lateral portion 128, and second vertical portion 129. Second vertical portion 129 may include contacting surface 129a for forming an electrical connection with a connector insert contact.

In this specific example, contact 120 may include additional portions. These additional portions may help to improve the inward lateral force applied to contacts of a connector insert. Specifically, contacts 120 may include a third vertical portion 123 extending in a downward direction, a third lateral portion 124, and a fourth vertical portion 125 extending in an upward direction. A fourth lateral portion 126 may join vertical portions 125 and 127.

In other embodiments of the present invention, these additional portions may not be included and instead first lateral surface mount contacting portion 122 may be directly connected to, or merged with, first vertical portion 127. This simplification may reduce a length of contact 120 and may allow a reduction in the width of the connector receptacle. This or other contact simplification may also reduce the amount of mechanical support needed by the contacts thereby possibly simplifying the connector receptacle.

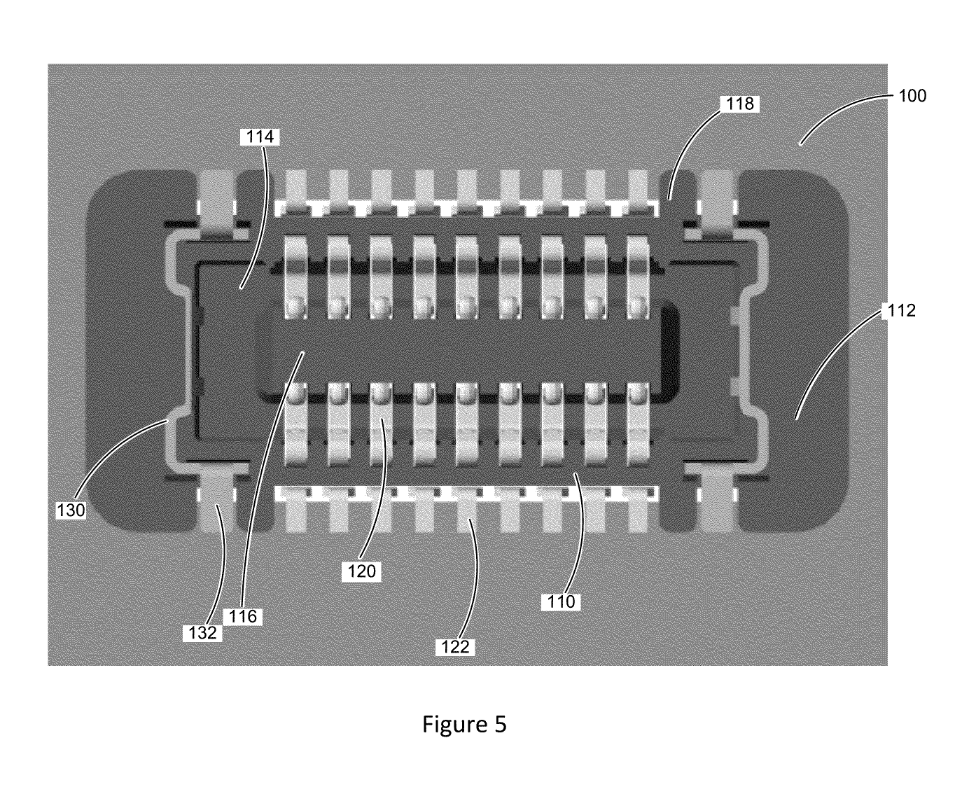

FIG. 5 illustrates a top view of a connector receptacle according to an embodiment of the present invention. As before, housing 110 may support a number of contacts 120. Contacts 120 may include surface mount contacting portions 122. Housing 110 may include a recess 114 around a central raised portion 116. Ground contacts 130 may be placed at ends of housing 110 and may include surface mount contacting portions 132. Housing 110 may further include printed circuit board overlap portions 112 and 118 for mechanical support and to prevent the connector receptacle from being pushed into opening 105 when a connector insert is inserted into the connector receptacle.

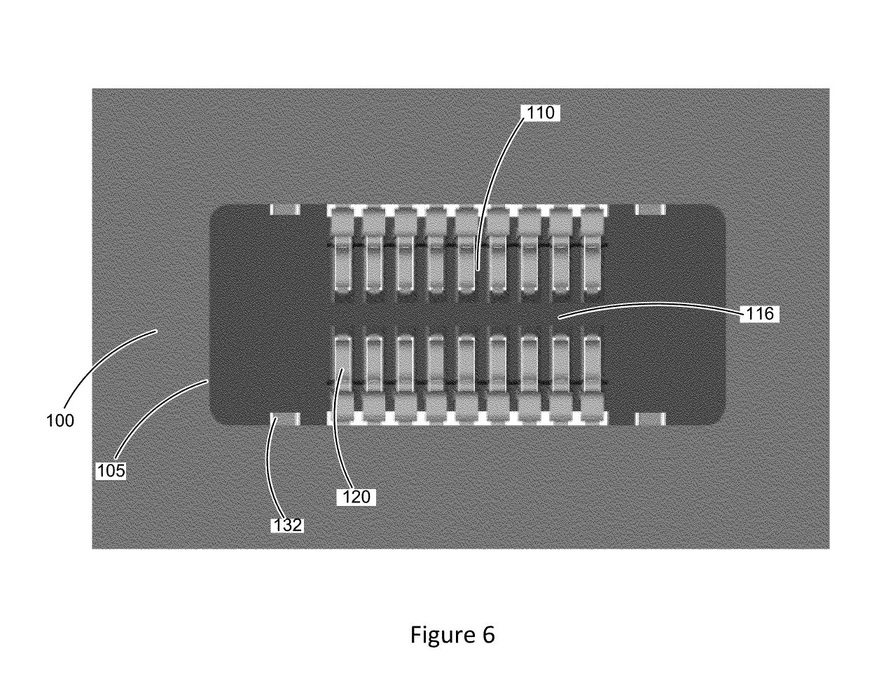

FIG. 6 illustrates an underside view of a connector receptacle according to an embodiment of the present invention. As before, the connector receptacle may include housing 110 supporting a number of contacts 120. Housing 110 may further include central portion 116 between rows of contacts 120. The connector receptacle may be located in an opening 105 in printed circuit board or other substrate 100. A portion of ground surface mount contacting portion 132 may be visible from the underside as shown.

Embodiments of the present invention may provide a method of assembling a connector receptacle. For example, a housing 110 having openings in an underside may be provided. Contacts 120 may be inserted through openings in an underside of housing 110. Ground contacts 130 may be placed in housing 110 via a top side of housing 110.

Various embodiments of the present invention may provide a connector receptacle or connector insert located in a recess of a printed circuit board or other appropriate substrate. In this case, a bottom part of the printed circuit board below the recess may provide mechanical support for the connector receptacle insert. In some embodiments of the present invention, it may be easier to place the connector receptacle or connector insert an opening in a printed circuit board or other appropriate substrate. More specifically, it may be easier to form an opening than a recess in a printed circuit board. For example, it may be easier to route an opening through a printed circuit board than it is to form a recess in a top surface of the printed circuit board. Accordingly, embodiments of the present invention may include one or more support structures to provide support for the connector insert receptacle. These support structures may help prevent a connector receptacle from being pushed through the opening when a connector insert is inserted into the connector receptacle. Also, these support mechanisms may provide support for individual contacts in the connector receptacle. An example is shown in the following figure.

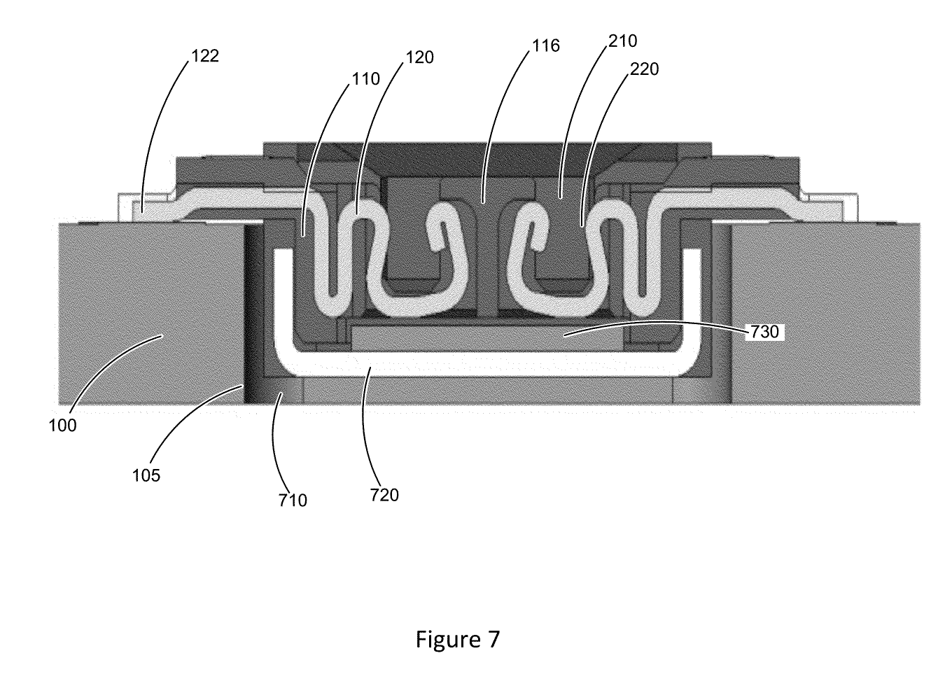

FIG. 7 illustrates a board-to-board connector system including a connector receptacle having support mechanisms according to an embodiment of the present invention. This connector receptacle may be placed in opening 105 in printed circuit board 100. As before, the connector receptacle may include housing 110 supporting a number of contacts 120. Contacts 120 may include lateral surface mount portions 122. A connector insert housing 210 may be inserted into the connector receptacle such that contacts 220 in the connector insert are mated with contacts 120 in the connector receptacle. As before, a raised central portion 116 on the connector receptacle may be aligned to fit in a recess in housing 210 of the connector insert.

The connector receptacle may include shell 710 as a support mechanism. Shell 710 may be arranged to have a bottom surface that is at least approximately aligned with a bottom surface of printed circuit board 100. This arrangement may allow a the connector receptacle to be properly aligned with the printed circuit board 100 when the connector receptacle and printed circuit board 100 are placed on a flat surface, such as an enclosure of a device. Shell 710 may be attached to housing 110. For example, shell 710 may be attached to housing 110 such that it works with or instead of overlap portions 112 and 118 (not shown) to provide support for the connector receptacle and connector receptacle contacts 120. Shell 710 may be formed of plastic, metal, or other conductive or nonconductive material. When shell 710 is formed of metal, it may electrically contact or be formed with ground contacts or hold downs 130 (not shown) or other ground contacts in the connector receptacle. In this way, shell 710 may form an electrical magnetic interference shield around a bottom of the connector receptacle. This shield may act in conjunction with a shielding provided by cowling 300 (when it is formed of metal) to help shield contacts 120 in the connector receptacle and contacts 220 in the connector insert.

In other embodiments of the present invention, other structures may be used in conjunction with, or instead of, shell 710. For example, supporting plane 720 may be included. In this case, shell 710 may be formed of plastic or other nonconductive material, while supporting plane 720 may be metallic, though in other embodiments of the present invention, supporting plane 720 may be plastic or nonconductive material as well, or both shell 710 and supporting plane may be metallic. Where supporting plane 720 is metallic, it may be electrically connected to or formed with ground contacts or hold downs 130 or other ground contacts to form an electromagnetic interference shield as before. Where supporting plane 720 is metallic, insulating layer 730 may be used to electrically isolate contacts 120 from supporting plane 720. Insulating layer 730 may be formed of tape, foam, plastic, or other nonconductive material.

In other embodiments of the present invention, support for contacts 120 may be provided by housing 110 itself. In various embodiments of the present invention, contacts 120 may be simplified, for example as shown above, such that a reduced amount of support is needed.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. An electronic device comprising:
a printed circuit board having a top surface, wherein a portion of the top surface is absent to form a first region; and
a board-to-board connector at least partially located in the first region, the board-to-board connector comprising a housing supporting a plurality of contacts.

2. The electronic device of claim 1 wherein the first region is a recess in a top surface of the printed circuit board.

3. The electronic device of claim 1 wherein the first region is an opening from a top surface to a bottom surface of the printed circuit board.

4. The electronic device of claim 3 wherein the housing further comprises an overlap portion to overlap a portion of the printed circuit board near the opening.

5. The electronic device of claim 1 wherein each of the plurality of contacts comprises:
a first lateral surface mount contact portion;
a first vertical portion extending in a downward direction, the first vertical portion including a first contacting surface;
a second lateral portion attached to the first vertical portion and extending away from the first lateral surface mount contact portion; and
a second vertical portion attached to the second lateral portion and extending in an upward direction, the second vertical portion including a second contacting surface.

6. The electronic device of claim 5 wherein at least one of the plurality of contacts further includes:
a third vertical portion connected to the first lateral surface mount contact portion and extending in a downward direction;
a third lateral portion attached to the third vertical portion and extending away from the first lateral surface mount contact portion;
a fourth vertical portion attached to the third lateral portion and extending in a downward direction; and
a fourth lateral portion attached between the fourth vertical portion and the first vertical portion.

7. The electronic device of claim 5 wherein for at least one contact in the plurality of contacts, the first lateral surface mount contact portion is attached to the first vertical portion.

8. A receptacle for a board-to-board connector system, the receptacle comprising:
a housing supporting a plurality of contacts, each contact including:
a first lateral surface mount contact portion;
a first vertical portion extending in a downward direction, the first vertical portion including a first contacting surface;
a second lateral portion attached to the first vertical portion and extending away from the first lateral surface mount contact portion; and
a second vertical portion attached to the second lateral portion and extending in an upward direction, the second vertical portion including a second contacting surface.

9. The receptacle of claim 8 wherein at least one of the plurality of contacts further includes:
a third vertical portion connected to the first lateral surface mount contact portion and extending in a downward direction;
a third lateral portion attached to the third vertical portion and extending away from the first lateral surface mount contact portion;
a fourth vertical portion attached to the third lateral portion and extending in a downward direction; and
a fourth lateral portion attached between the fourth vertical portion and the first vertical portion.

10. The receptacle of claim 8 wherein for at least one contact in the plurality of contacts, the first lateral surface mount contact portion is attached to the first vertical portion.

11. The receptacle of claim 9 wherein the housing is arranged to fit in an opening of a printed circuit board.

12. The receptacle of claim 11 wherein the first lateral surface mount portion of each contact is arranged to form an electrical connection with a pad on a surface and near the opening of the printed circuit board.

13. The receptacle of claim 12 wherein the housing further comprises an overlap portion to overlap a portion of the printed circuit board near the opening.

14. The receptacle of claim 13 wherein the housing comprises a recess, the recess around a central raised portion, wherein the recess is arranged to accept a raised portion of a connector insert and the central raised portion is arranged to fit in a recess in the raised portion of the connector insert.

15. A method of manufacturing an electronic device, the method comprising:
receiving a printed circuit board;
forming a first region in a surface of the printed circuit board;
receiving a housing for a board-to-board receptacle;
inserting a plurality of contacts into the housing, the plurality of contacts to mate with corresponding contacts of a connector insert;
inserting the housing and plurality of contacts into the first region;
attaching a first lateral surface mount contact portion of each of the plurality of contacts to a corresponding pad on a surface of the printed circuit board near the first region;
attaching a board-to-board insert to a flexible circuit board;
inserting the board-to-board insert into the board-to-board receptacle.

16. The method of claim 15 wherein the first region is a recess in a top surface of the printed circuit board.

17. The method of claim 15 wherein the first region is an opening from a top surface to a bottom surface of the printed circuit board.

18. The method of claim 17 wherein each of the plurality of contacts comprises:
the first lateral surface mount contact portion;
a first vertical portion extending in a downward direction, the first vertical portion including a first contacting surface;
a second lateral portion attached to the first vertical portion and extending away from the first lateral surface mount contact portion; and
a second vertical portion attached to the second lateral portion and extending in an upward direction, the second vertical portion including a second contacting surface.

19. The method of claim 18 wherein at least one of the plurality of contacts further includes:
a third vertical portion connected to the first lateral surface mount contact portion and extending in a downward direction;
a third lateral portion attached to the third vertical portion and extending away from the first lateral surface mount contact portion;
a fourth vertical portion attached to the third lateral portion and extending in a downward direction; and
a fourth lateral portion attached between the fourth vertical portion and the first vertical portion.

20. The method of claim 18 wherein for at least one contact in the plurality of contacts, the first lateral surface mount contact portion is attached to the first vertical portion.
